(19) United States
(12) Patent Application Publication
(10) Pub. No.: US 2026/0311962 A1
(43) Pub. Date: Oct. 8, 2026

(54) PRECISE AND ACCURATE CRITICAL DIMENSION MEASUREMENT BY MODELING LOCAL CHARGING DISTORTION

(71) Applicant: ASML Netherlands B.V., Veldhoven (NL)

(72) Inventors: Hongquan ZUO, San Jose, CA (US); Kangsheng QIU, San Jose, CA (US); Mosong CHENG, Pleasanton, CA (US); Lingling PU, San Jose, CA (US)

(73) Assignee: ASML Netherlands B.V., Veldhoven (NL)

(21) Appl. No.: 19/481,760

(22) PCT Filed: Apr. 8, 2024
(86) PCT No.: PCT/EP2024/059488

§ 371 Date: Nov. 5, 2025

Related U.S. Application Data
(60) Provisional application No. 63/464,503, filed on May 5, 2023.

(51) Int. Cl. H01J 37/28

(52) U.S. Cl. CPC H01J 37/28; H01J 2237/24564; H01J 2237/24592

(57) ABSTRACT

A system and method for characterizing and predicting a local charging effect in wafer critical dimension measurements. The system and method may comprise a critical dimension model including a charging coefficient for each class of features on a wafer under inspection. The charging coefficients may be based on dimensional model may further comprise an initial charging status and a term describing the change in local charging effects as a function of time, or of the number of measurement scans in a given area.

### CROSS-REFERENCE TO RELATED APPLICATION

This application claims priority to U.S. Application No. 63/464,503 which was filed on 5 May 2023, and which is incorporated herein in its entirety by reference.

### FIELD

The description herein relates to detectors that may be useful in the field of charged particle beam systems, and more particularly, to systems and methods that may be applicable to charged particle detection for, e.g., defect inspection or metrology.

### BACKGROUND

Detectors may be used for sensing physically observable phenomena. For example, charged particle beam tools, such as electron microscopes, may comprise detectors that receive charged particles projected from a sample and that output detection signals. Detection signals may be used to reconstruct images of sample structures under inspection and may be used for, e.g., metrology, overlay, or defect inspection. For example, wafer critical dimension (CD) measurement is a major application for SEM metrology products. CD measurement may provide geometric information of printed patterns for guiding R&D in advanced semiconductor nodes, or it may provide an important performance indicator for monitoring product quality in high volume semiconductor manufacturing.

Metrology and defect inspection in a sample is increasingly important in the manufacturing of semiconductor devices, which may include large numbers of densely packed, miniaturized integrated circuit (IC) components. Inspection systems may be provided for this purpose. However, existing detection systems may suffer from distortion and other imaging errors due to local surface charging effects on a sample under inspection.

### SUMMARY

Embodiments of the present disclosure provide systems and methods for detection based on charged particle beams. Some embodiments of the present disclosure provide a charged particle beam method. The method may comprise: performing a first measurement of a parameter of a feature on a sample using a first scan of a charged particle beam apparatus; performing a second measurement of the parameter of the feature on the sample using a second scan of the charged particle beam apparatus; estimating a first value of a charging effect on the feature for the first scan and a second value of the charging effect on the feature for the second scan based on a charging effect model; and adjusting data from the first measurement and the second measurement based on the first value and the second value.

Some embodiments of the present disclosure provide a non-transitory computer-readable medium. The non-transitory computer-readable may store a set of instructions that is executable by at least one processor of an apparatus to cause the apparatus to perform the above method.

Some embodiments of the present disclosure provide a charged particle beam apparatus. The charged particle beam apparatus may comprise: a charged particle beam source configured to generate a beam of primary charged particles; an optical system configured to direct the beam of primary charged particles at a sample surface to inspect the sample surface; a charged particle detector configured to detect charged particles returned from the sample surface; and a controller comprising one or more processors and configured to cause the charged particle beam apparatus to perform the above method.

Some embodiments of the present disclosure provide a charged particle beam method. The method may comprise: performing a plurality of measurements of a parameter of a feature on a sample using a plurality of scans of a charged particle beam apparatus; estimating charging effects on the feature for the plurality of measurements using a charging effect model; and adjusting the plurality of measurements based on the estimated charging effects to yield a plurality of corrected measurements; and generating an inspection result based on the plurality of corrected measurements.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings.

FIG. 1 is a diagrammatic representation of an exemplary electron beam inspection (EBI) system, consistent with embodiments of the present disclosure.

FIGS. 2A-B are diagrams illustrating a charged particle beam apparatus that may be an example of an electron beam tool, consistent with embodiments of the present disclosure.

FIGS. 3A-B are diagrammatic representations of an example line edge detection in a charged particle beam image, consistent with embodiments of the present disclosure.

FIG. 4 is a diagrammatic representation of an example calculation process for CD precision, according to a comparative embodiment.

FIG. 5 is a diagrammatic representation of an example calculation process for CD precision, consistent with embodiments of the present disclosure.

FIGS. 6A-6D are diagrammatic representations of example plots of CD measurement vs charging time, consistent with embodiments of the present disclosure.

FIG. 7 is a flowchart illustrating an example method for detecting charged particles, consistent with embodiments of the disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims. For example, although some embodiments are described in the context of utilizing charged-particle beams (e.g., electron beams), the disclosure is not so limited. Other types of charged particle beams (e.g., photon beams) may be similarly applied. Furthermore, other imaging systems may be used, such as optical imaging, photodetection, x-ray detection, or the like.

Electronic devices are constructed of circuits formed on a piece of silicon called a substrate. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a fingernail and yet may include over 2 billion transistors, the size of each transistor being less than 1/1,000th the width of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning charged-particle microscope, such as a scanning electron microscope (SEM). A SEM can be used to image these extremely small structures, in effect, taking a “picture” of the structures. The image can be used to determine if the structure was formed properly, and also if it was formed in the proper location. If the structure is defective, then the process can be adjusted so the defect is less likely to recur. To enhance throughput (e.g., the number of samples processed per hour), it is desirable to conduct inspection as quickly as possible.

The working principle of a SEM is similar to a camera. A camera takes a picture by receiving and recording intensity of light reflected or emitted from people or objects, pixel by pixel. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and, in some instances, stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

In some inspection processes, such as critical dimension (CD) metrology, a charged particle image may be used to measure widths of the smallest features printed on the sample to determine how well the printed pattern meets design specifications. For instance, an electron beam may be scanned across the surface topography of the pattern, such as a set of repeating lines and spaces, taking pixel-by-pixel intensity measurements as it goes. Each line may have a substantially flat, raised upper surface. The lower spaces between each line may also be relatively flat, while the transition between line and space may comprise a sharp vertical line edge. In the electron beam image, the pixel intensities at these edge transitions may contrast sharply with the flat regions around them, providing a means of measuring the widths of these features.

A problem occurs when the charged particles in a scanning beam create unwanted electrical effects on the sample surface during the scan. For example, the scanning beam may cause the local area of a feature to acquire a net electrical charge, which in turn alters the emission of electrons back to the detector surface. As the beam scans across a feature, this continuous charge buildup may cause the first edge of the feature to produce a different intensity measurement than the second edge, even if the two edges are symmetrical. Further, an inspection process may involve taking many scans of the same area and integrating the signals from each scan to form a final image. This may result in further charge buildup that increases with each successive scan. Thus, local charging effects may distort a charged particle beam image, leading to errors in CD metrology or defect inspection.

Embodiments of the present disclosure provide systems and methods for identifying and modeling these charging effects so that they may be accounted for in charged particle beam inspections. For example, some embodiments of the present disclosure may provide a charging model for estimating the change in charging effects on a given pattern feature with each successive beam scan on the feature. The model may comprise a first term representing the actual parameter being measured, and a second term comprising a charging function. The model may be used to apply a correction to the measurement data such that the data better represents the actual feature. The model may be used to perform improved calculations of measurement precision. Further, the model may be used to generate a high quality inspection image. The image may comprise corrections of distortion or other imaging aberration based on the modeled charging effects.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams (such as proton beams) may be similarly applied. Furthermore, systems and methods for detection may be used in other imaging systems, such as optical imaging, photon detection, proton detection, x-ray detection, ion detection, or the like. Photon detection may comprise light in the infrared, visible, UV, DUV, EUV, x-ray, or any other wavelength range. Therefore, while detectors in the present disclosure may be disclosed with respect to electron detection, some embodiments of the present disclosure may be directed to detecting other charged particles or photons.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C.

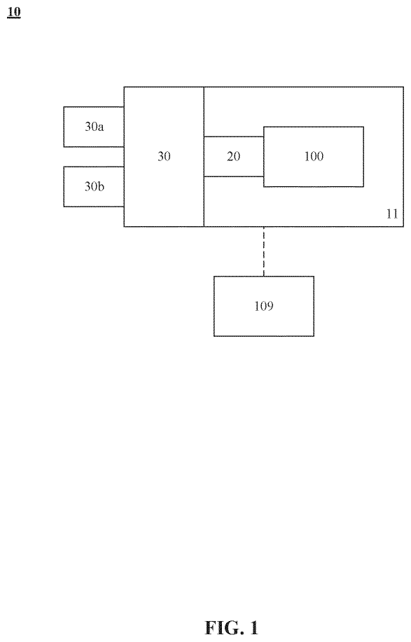

Reference is now made to FIG. 1, which illustrates an exemplary electron beam inspection (EBI) system 10 that may be used for wafer inspection, consistent with embodiments of the present disclosure. As shown in FIG. 1, EBI system 10 includes a main chamber 11 a load/lock chamber 20, an electron beam tool 100 (e.g., a scanning electron microscope (SEM)), and an equipment front end module (EFEM) 30. Electron beam tool 100 is located within main chamber 11 and may be used for imaging. EFEM 30 includes a first loading port 30a and a second loading port 30b. EFEM 30 may include additional loading ports. First loading port 30a and second loading port 30b receive wafer front opening unified pods (FOUPs) that contain wafers (e.g., semiconductor wafers or wafers made of other materials) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a wafer under inspection. The interactions of the primary electrons with the wafer may result in secondary particle beams being formed. The secondary particle beams may comprise backscattered electrons, secondary electrons, or Auger electrons, etc. resulting from the interactions of the primary electrons with the wafer. Characteristics of the secondary particle beams (e.g., intensity) may vary based on the properties of the internal or external structures or materials of the wafer, and thus may indicate whether the wafer includes defects.

The intensity of the secondary particle beams may be determined using a detector. The secondary particle beams may form beam spots on a surface of the detector. The detector may generate electrical signals (e.g., a current, a charge, a voltage, etc.) that represent intensity of the detected secondary particle beams. The electrical signals may be measured with measurement circuitries which may include further components (e.g., analog-to-digital converters) to obtain a distribution of the detected electrons. The electron distribution data collected during a detection time window, in combination with corresponding scan path data of the primary electron beam incident on the wafer surface, may be used to reconstruct images of the wafer structures or materials under inspection. The reconstructed images may be used to reveal various features of the internal or external structures or materials of the wafer and may be used to reveal defects that may exist in the wafer. There are two ways for CD-SEM to perform image reconstruction based on the signal: based on amplitude integral of the signal in each scanning pixel; or based on signal pulse edge detection and discrimination. At each scanned pixel location, multiple electrical signal pulses collected by different detector segments may have different pulse shapes. These various pulse shapes contain information about the electron energy distribution collected by the detector. Electrons with higher energy can cause faster rising times in the electrical pulse shape. With multiple segments of the detector (4 channels), up to 4 pulse edge detection image channels can be used to perform electron energy analysis, yielding higher SEM resolution.

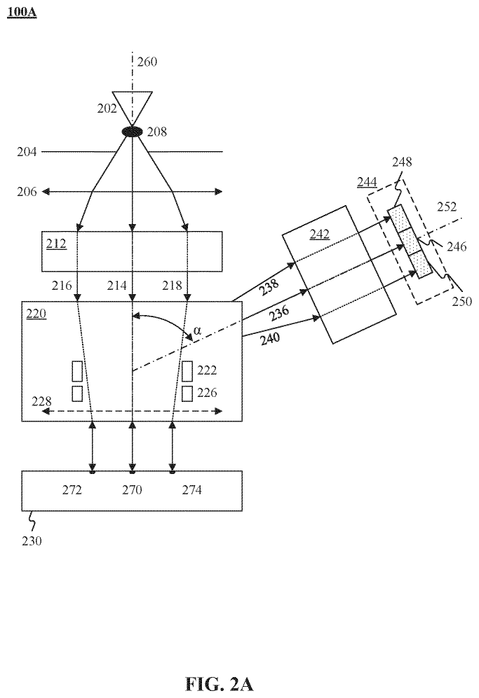

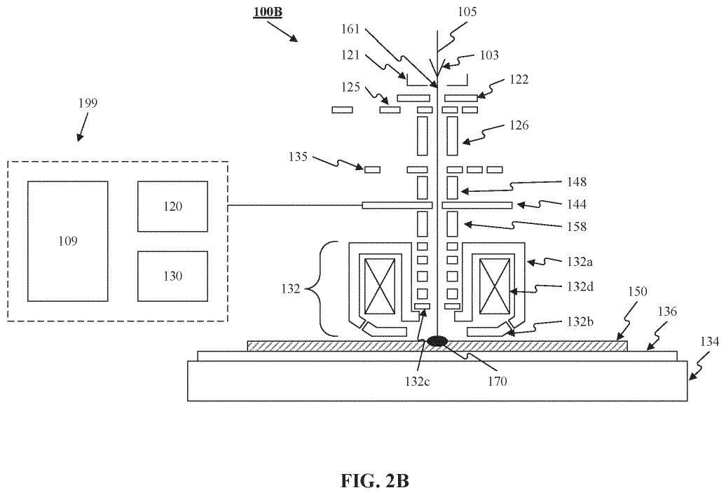

FIG. 2A illustrates a charged particle beam apparatus that may be an example of electron beam tool 100, consistent with embodiments of the present disclosure. FIG. 2A shows an apparatus that uses a plurality of beamlets formed from a primary electron beam to simultaneously scan multiple locations on a wafer.

As shown in FIG. 2A, electron beam tool 100A may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 100A. Secondary optical system 242 and electron detection device 244 may be aligned with a secondary optical axis 252 of apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principle plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230.

The generated signals may represent intensities of secondary electron beams 236, 238, and 240 and may be provided to an image processing system (e.g. such as image processing system 199 provided in FIG. 2B below) that is in communication with detection device 244, primary projection optical system 220, and motorized wafer stage. The movement speed of motorized wafer stage may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary electron beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary electron beams 236, 238, and 240 that may have different intensities. Therefore, by mapping the intensity of secondary electron beams 236, 238, and 240 with the areas of wafer 230, the image processing system may reconstruct an image that reflects the characteristics of internal or external structures of wafer 230.

Detection sub-regions 246, 248, and 250 may include separate detector packages, separate sensing elements, or separate regions of an array detector. In some embodiments, each detection sub-region may include a single sensing element.

While FIG. 2A shows detector 244 having several detection sub-regions aligned with secondary optical axis 252, it is appreciated that other multi-beam detector schemes may exist. For example, it is appreciated that a detector may correspond with each beamlet, such as a different detector for each of beamlets 214, 216, 218. It is appreciated that these different detectors may be positioned under the primary column corresponding to primary axis 260. For example, these different detectors could be positioned between primary projection optical system 220 and the wafer stage.

Another example of a charged particle beam apparatus will now be discussed with reference to FIG. 2B. An electron beam tool 100B (also referred to herein as apparatus 100B) may be an example of electron beam tool 100 and may be similar to electron beam tool 100A shown in FIG. 2A. However, different from apparatus 100A, apparatus 100B may be a single-beam tool that uses only one primary electron beam to scan one location on the wafer at a time.

As shown in FIG. 2B, apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may be communicatively coupled with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

FIG. 2B illustrates a charged particle beam apparatus that may use a single primary beam configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 2B shows an example of detector 144 having an opening at its center. However, some embodiments may use a detector placed off-axis relative to the optical axis along which the primary electron beam travels. For example, as in the embodiment shown in FIG. 2A, discussed above, a beam separator 222 may be provided to direct secondary electron beams toward a detector placed off-axis. Beam separator 222 may be configured to divert secondary electron beams by an angle α toward an electron detection device 244, as shown in FIG. 2A.

In some embodiments of the disclosure, a PIN detector may be used as an in-lens detector in a retarding objective lens SEM column of EBI system 10. The PIN detector may be placed between a cathode for generating an electron beam and the objective lens. The electron beam emitted from the cathode may be potentialized at −BE keV (typically around −10 kV). Electrons of the electron beam may be immediately accelerated and travel through the column. The column may be at ground potential. Thus, electrons may travel with kinetic energy of BE keV while passing through opening 145 of detector 144. Electrons passing through the pole piece of the objective lens, such as pole piece 132a of objective lens assembly 132 of FIG. 2B, may be steeply decelerated down to landing energy LE keV as the wafer surface potential may be set at −(BE−LE) keV.

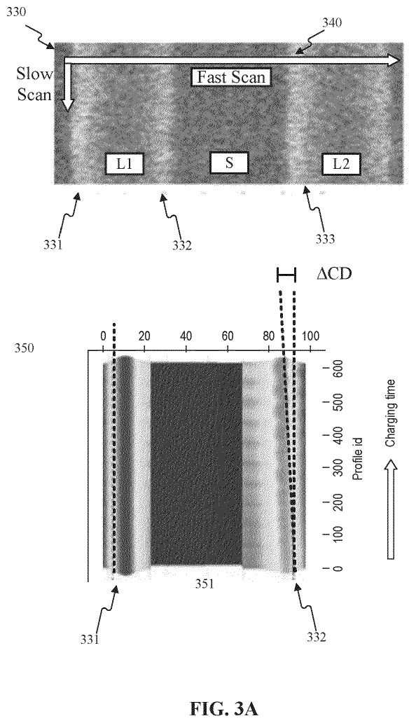

FIGS. 3A-B illustrate a charging problem encountered during a charged particle beam process, such as a process performed by, e.g., any of apparatus 100, 100A, or 100B of FIGS. 1-2B. The top of FIG. 3A illustrates a SEM image 330 of a portion of a wafer. The portion comprises first and second lines L1 and L2 printed on the wafer and separated by a space S. The bottom of FIG. 3A illustrates a change in the signal profile 351 of a single scan line 340 from image 330, as function of the increase in charging time with each successive scan of the line 340. FIG. 3B schematically illustrates interaction volumes in a cross-sectional view of lines L1/L2 and space S.

An electron beam may scan across a field of view (FOV) of the electron beam tool in a “fast scan” direction to measure a series of pixel intensities across a single line, such as line 340. The beam may then be deflected in a perpendicular “slow scan” direction to repeat the process at the next line. Each dot in the grayscale image 330 may represent a single pixel intensity value measured at a detector surface. The intensity value may be a function of the number or energy of electrons emitted from the wafer at that point. As the electron beam scans in a fast scan direction across the material of line L1, the beam may cause the material to build up an excess electric charge at its trailing edge 332. For example, in some embodiments, the landing energy of the beam may cause negatively charged electrons to be emitted from the surface in a sufficient amount to leave behind an appreciable net positive charge. The increased positive charge in the line material may attract the electrons that would otherwise be emitted, affecting the number or energy of electrons at the detector surface. Thus, the resulting image of a line edge may suffer distortions or other measurement errors due to the charging effect. Because the effect may be scan-direction dependent as further discussed below, the buildup may not be as pronounced at the leading edge of a line, such as leading edge 331 of line L1, as it is at the trailing edge 332. Therefore a dimensional measurement, such as a CD measurement of the width of a line L or space S, may become distorted. For instance, trailing edge 332 may appear in image 330 with an offset or other aberration from where it is actually located on the wafer.

The bottom of FIG. 3A is a graph 350 illustrating this distortion. Graph 350 shows a change in the signal profile 351 of scan line 340 as function of charging time. An initial scan at time t=0 (at bottom) indicates the initial measured locations of edge 331 332. As charging time increases up the vertical axis with each successive scan of line 340, the measured location of leading edge 331 remains substantially constant. But the measured location of trailing edge 332 of line L1 exhibits a drift as charge accumulates there. The average of these scans may be used to form the distorted image of line 340, resulting in a poor measurement of the width of line L1. For example, a measured width of line L1 may decrease as charge accumulates. A corresponding issue may occur when measuring, e.g., a width of space S between trailing edge 332 of line L1 and leading edge 333 of line L2. Because measurements of trailing edge 332 may drift to the left while measurements of leading edge 333 remain substantially constant, the measured width of space S may increase.

FIG. 3B schematically illustrates this issue in a cross-sectional view of a first scan (at top) and a second or subsequent scan (at bottom). The first scan may be, e.g., an initial scan or another scan that occurs prior to the second scan. Each scan depicts four irradiation points of an electron beam 361 at the leading and trailing edges of lines L1 and L2 relative to the fast scan direction 340, along with their corresponding interaction volumes 334. The interaction volume may be the spatial region within which incident electrons interact with the material of wafer 330 or lines L to generate, e.g., secondary and backscattered electrons. The interaction volume may vary with properties of the material (such as density, conductivity, etc.) as well as properties of the beam (such as landing energy, incident angle, etc.). For example, the density of a material may have an effect on the mean free path of electrons from beam 3651 or wafer 330. The mean free path in a material may be thought of as the average distance a particle will travel before colliding or interacting with another particle, thus changing its trajectory or energy. As signal profiles 351 depend on the secondary electrons emitted to a detector surface, the profile varies in part according to the interaction volume.

As seen at the top of FIG. 3B, each interaction volume may be substantially symmetrical, resulting in substantially similar signal profiles 351. However, as the number of scans increases, a positive charge may accumulate at the trailing edges of lines L1 and L2, resulting in a net electric field from trailing edge 332 to leading edge 331. Even a small change in electric field will produce an appreciable change in the trajectory and energy of secondary particles, resulting in a distorted mean free path and interaction volume 335 at the trailing edges. This distortion results in a distorted signal profile, as shown by the offset between irradiated and measured locations of trailing edges at the bottom of FIG. 3B.

It is noted that the above issue is discussed with respect to positive charge accumulation using an electron beam. However, embodiments of the present disclosure are not limited to this. For instance, in some embodiments an electron beam may produce a negative charging effect depending on, e.g., beam properties such as landing energy and beam current, or material properties such as electrical conductivity and electrical contact with other portions of the wafer. Further, a similar effect may be found in other charged particle systems, such as proton or other ion beams, etc.

A CD measurement may thus be represented by the following formula:

$${CD}_{m} = {CD}^{*} + {CD}^{\#} + Δ CD \qquad ( eqn . 1 )$$

where CDₘ is the measured CD value (e.g., the values represented in graph 350), CD* represents the actual CD, CD^{#} is a CD variation caused by the local charging effect, and ΔCD represents measurement error (e.g., a difference between the instant measurement and the average measurement).

Comparative methods of determining CD may fail to adequately account for the charging effect term CD^{#}. This may result in poor CD accuracy (how well the determined CD agrees with the actual CD) and CD precision (how well successive measurements agree with each other). Regarding accuracy, comparative models may have no means of predicting local charging distortion. Instead, an initial scan may be approximated as a measurement taken in the absence of local charging, even if the measured feature has an initial charging value. Regarding CD precision, comparative methods may comprise taking an averaged 3σ(ΔCD) using the following formulas:

$$C {D}_{m e a n ( i )} ≅ {CD}^{*} + {CD}_{( i )}^{\#} \qquad ( eqn . 2 )$$

$$Δ {CD}_{m ( i . j )} = {CD}_{m ( i . j )} - {CD}_{m e a n ( i )} \qquad ( eqn . 3 )$$

$$precision ( Δ {CD}_{m} ) = mean ( 3 σ ( Δ C {D}_{m \text{(*} . j )} ) ) \qquad ( eqn . 4 )$$

Here, i may be a run index (indicating the scanning measurement number), and j may be an index of the measurement area (such as a die, a select FOV within each die, or another region of a sample). Therefore, CD_{m(i,j)} (see eqn. 1) may indicate the i^{th} CDₘ measurement for the j^{th} position on a wafer. CDₘₑₐₙ₍ᵢ₎ (eqn. 2) may indicate the average CD measurement at all positions j for the i^{th} measurement run. ΔCD_{m(i,j)} (eqn. 3) may indicate the difference between an individual measurement CD_{m(i,j)} and the average of all measurements of the given run i, or simply (eqn. 1)-(eqn. 2). Finally, precision(ΔCDₘ) (eqn. 4) may be determined as the mean of 3σ(ΔCD_{m(*,j)}) for each location j, as further discussed below.

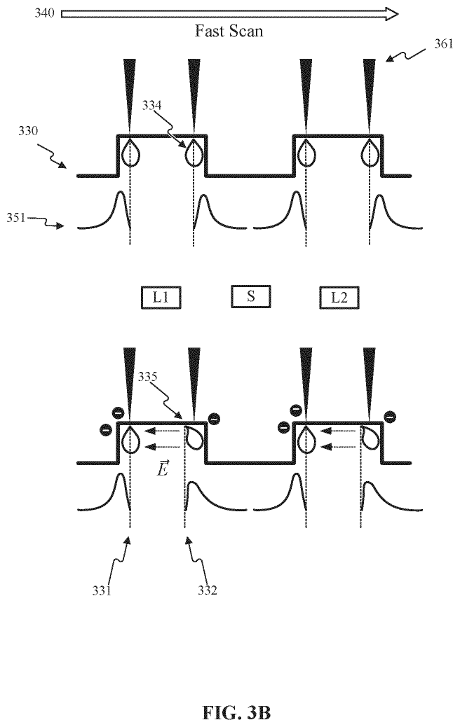

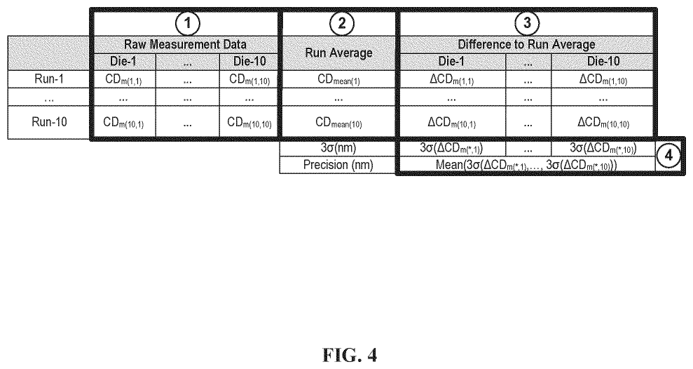

FIG. 4 illustrates an example CD precision calculation process, according to a comparative embodiment. The example calculation uses ten measurement runs at ten die locations, such that i=j=10. The data indicated in boxes 1-4 of FIG. 4 may correspond to steps 1-4 of the process, as well as to eqns. 1-4, respectively.

At step 1, raw CD measurement data is generated for runs i=1 . . . 10 at locations j=1 . . . 10 using, e.g., a charged particle beam tool such as a SEM tool. In some embodiments, the CD measurements at location j may comprise a width, or an average of all widths, of a chosen critical feature (such as lines or spaces as illustrated in FIGS. 3A-B) within the location j to yield a 10×10 matrix of values shown at box 1. At step 2, each run i may be averaged over all locations j to determine the average for each run i=1 . . . 10. At step 3, a measurement error ΔCD may be estimated for each value in box 1 by subtracting its corresponding run average in box 2. Finally, in step 4, the 3a value of ΔCD is calculated for each die location j over all runs i. The precision of the CD measurements may then be estimated by taking the mean of these 3σ values, or mean(3σ(ΔCDₘ)).

The system of FIG. 4 relies on statistical analysis of the raw measurements, and fails to separate charging effect errors from random measurement errors or actual CD values. Therefore, measurement accuracy and measurement precision both suffer. For example, the above calculations may rely on the initial run i=1 as a baseline measurement, which assumes that the structures under inspection have no initial charging status. However, this may not be the case. The structures may have to carry some charge value as a consequence of prior processes, material and structural properties, contact with neighboring elements, etc. Further, the estimate of measurement error at step 3 relies on poor assumptions about what might be responsible for the observed variation in measurement values, such as charging effects, actual CD variation, measurement noise, etc. Additionally, the above system may rely on a fairly short averaging duration, such as by averaging CD from single runs as in step 2 discussed above. This fails to account for longer trending information, the modeling and investigation of which could yield a deeper understanding of long-term charging effects. Finally, this pure statistical analysis approach is problematic in that it depends on the number of runs and dies being averaged. The performance of the precision result could drop with limited runs or dies, but adding more runs also risks introducing further unaccounted-for charging effects.

Embodiments of the present disclosure provide systems and methods for characterization and prediction of local charging effects in charged particle beam inspections such as, e.g., CD measurement. By providing an accurate model of local charging effects, CD and other measurements may be performed with improved accuracy and precision.

For example, a model for characterizing and predicting local charging effects in CD measurements according to embodiments of the present disclosure may take the following form:

$$C {D}_{m o d e l ( i , j )} = {a}_{j} + b * ln ( i + {c}_{j} ) ≅ {CD}_{j}^{*} + {C}_{i , j}^{\#} \qquad ( eqn . 5 )$$

where CD_{model(i,j)} is a model describing the i^{th} measured CD value at the j^{th} measurement location. Here, i may be referred to as a charging time index, as discussed below. The term aⱼ may represent the actual physical CD at the location j. The term b may represent a charging coefficient of the logarithmic charging function ln(i+cⱼ). Finally, cⱼ may represent an initial charging status.

The term i may be referred to as a charging time index because it may relate to the amount of charging time a feature location has been subjected to. However, because the amount of charging time may correspond to the number of scans previously performed in that location, in some embodiments, the index i may correspond the scan number as it does in eqns. 2-4 above. While the number 10 is frequently used as an example in the present disclosure, the number of scans may be any suitable number. For example, a CD measurement may comprise between 1 and 10, or 1 and 20 scans. Some measurements may require more scans due to poor image quality. For example, an overlay measurement may require, e.g., 10, 20, 30, 40, 50, 100, 200, or 500 scans or more. Furthermore, embodiments of the present disclosure may allow a greater number of scans to be integrated into an image, as discussed in more detail below. In some embodiments, the index i may indicate another parameter that relates to the charging time or charging amount received at the wafer location. For instance, the index i may be a time increment.

The term b may represent a charging coefficient of logarithmic charging function ln(i+cⱼ). Charging coefficient b may be designed to scale the magnitude of the logarithmic charging function to fit the charging effects of the features under inspection. Different values of b may be selected for different classes of features on a wafer under inspection. For example, a first value b₁ may be used for a first set of features on a wafer such as, e.g., the lines in a fine-pitch line/space pattern as discussed above with respect to FIGS. 3A-B. A second value b₂ may be applied to, e.g., an array of contact holes. The value of b may be determined based on various structural and material parameters of the features under inspection. For example, the size, shape, pitch, chemical and electrical properties, as well as the properties of neighboring features, coatings, substrate materials, etc., may be considered in determining b. The value of b may vary depending on parameters of the inspection process, such as landing energy, beam current, scanning number and frequency, etc. In general, b may be determined through model or experiment, by evaluation of a reference wafer or reference feature, may be derived from a lookup table based on calibration runs, may be estimated using AI or machine learning, or may generally be determined based on any suitable technique. Further, the values for b may be continuously or periodically refined using, e.g., feedforward or feedback adjustments.

Initial charging status cⱼ may represent the charging effects at the features under inspection during an initial run at i=0. Initial charging status cⱼ may be determined based on similar considerations to those discussed above with respect to b. However, in addition to, e.g., parameters of the inspection process, properties of the features under inspection and properties of connected or neighboring elements, the initial charging status may depend on historical information of the wafer, such as past manufacturing or inspection processes.

Logarithmic charging function ln(i+cⱼ) may be designed to model the change in charging effects as a function of charging time index i and initial charging status cⱼ. For instance, the modeled charging effects may comprise a change in CD, a shift in line edge position, an alignment shift, a film thickness, a defect parameter, a material parameter, a change in expected signal intensity value, or any other parameter. Further, while the exemplary formula of eqn. 5 uses a logarithmic function, it is noted that embodiments of the present disclosure are not limited to this. In general, any suitable function may be applied as necessary to fit the parameters of a particular application. In some embodiments, a charging function may comprise, e.g., logarithmic, exponential, polynomial, hyperbolic or other functions, or combinations of such functions.

Models according to embodiments of the present disclosure may be used to improve measurement accuracy of charged particle beam inspection processes, such as CD measurement. For example, the term aⱼ in the model of eqn. 5 may represent actual CD with the charging effects removed, resulting in a more accurate measurement. In some embodiments, a charging function such as b*ln(i+cⱼ) may be applied as a correction term CD_{i,j}^{#} in CD measurements. Obtaining more accurate values for measured or modeled CD may be advantageous in guiding advanced semiconductor node R&D, or providing improved process monitoring in semiconductor high volume manufacturing to improve device yield, reduce re-work, and provide better feed-forward/feedback process adjustments.

The improved accuracy may further be utilized to provide image correction. By accounting for the charging effects contained in raw data measurements, the image frame of each individual scan run may be corrected. When these frames are averaged together, the image may more accurately depict the contours and locations of features on the wafer. For example, line 332 in SEM image 330 of FIGS. 3A-B may be shifted and corrected to display its true location and shape with greater accuracy.

Such image correction may further improve imaging accuracy by allowing more frames to be averaged in a single image. This is because the increasing charged-induced errors of each successive scan may place an upper limit on the number of usable frames. Further scans may yield measurements that are too unreliable due to charge accumulation. However, when the charge effects can be predicted and substantially removed, a much larger number of frames may be included. This may be useful, e.g., for R&D applications when high-quality images are more important than inspection speed or throughput. The resulting high-frame images may yield improved measurement and analysis of CD or other parameters such as, e.g., linewidth or line edge roughness, edge placement error, sidewall angle, alignment, overlay, or other parameters.

In some embodiments of the present disclosure, a charging coefficient b may be utilized as a further inspection parameter. That is, models according to embodiments of the present disclosure may be used to identify a charging coefficient as a manner of, e.g., defect inspection. Because ethe charging coefficient b may describe, e.g., electrical and other material properties, the charging coefficient of a defective feature may be an outlier in the general coefficient distribution of similar features. For example, a feature that is improperly shorted to a substrate, or has some other unwanted electrical connection or disconnection, may be identified by evaluation its charging coefficient.

In addition to measurement accuracy, measurement precision may be improved according to embodiments of the present disclosure. For example, CD precision may be determined using the following formulas:

$$Δ C {D}_{m o d e l ( i . j )} = C {D}_{m ( i . j )} - C {D}_{m o d e l ( i , j )} \qquad ( eqn . 6 )$$

$$precision ( Δ {CD}_{m o d e l} ) = mean ( 3 σ ( Δ {CD}_{m o d e l \text{(*} . j )} ) ) \qquad ( eqn . 7 )$$

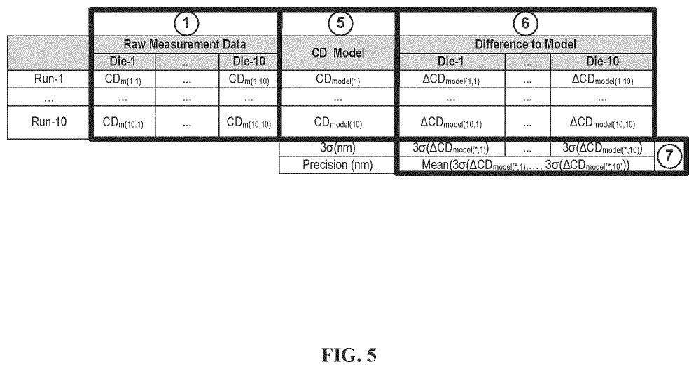

FIG. 5 illustrates an example CD precision calculation process, consistent with embodiments of the present disclosure. At step 1, raw CD measurement data may be generated for runs i=1 . . . 10 at locations j=1 . . . 10. The data may be generated using a charged particle beam tool such as, e.g., any of apparatus 100, 100A, or 100B of FIGS. 1-2B. At step 2, instead of relying on a run average of the raw data as in FIG. 4, a CD model such as, e.g., eqn. 5 may be calculated for each run. At step 3, a measurement error ΔCD may be estimated for each value in box 1 by subtracting its corresponding CD model in box 2. For example, in some embodiments, the measurement error may comprise a difference calculation according to eqn. 6 above. Finally, in step 4, the 3a value of ΔCD may be calculated for each die location j over all runs i. As seen in the first column of boxes 6-7 in FIG. 5, a first 3a value may be calculated for all 10 runs of die 1. At the next column, a second 3σ value may be calculated for all 10 runs of die 2, etc., up to a tenth 3σ value for all 10 runs of die 10. The precision of the CD measurements may then be estimated by taking the mean of these 3σ values, or mean(3σ(ΔCD_{model})) as shown at, e.g., eqn. 7.

The precision calculation according to eqns. 5-7 in FIG. 5 may provide a significant improvement over eqns. 2-4 of the comparative embodiment of FIG. 4, using the same raw data at box 1 in step 1. For example, studies on an experimental dataset indicate a precision value of 0.0309 nm when calculated using eqn. 7 in embodiments of the present disclosure, while comparative methods using eqn. 4 for the same raw data set may be, e.g., 0.0360 nm. Thus embodiments of the present disclosure may provide an improvement in CD precision of, e.g., 14% or more.

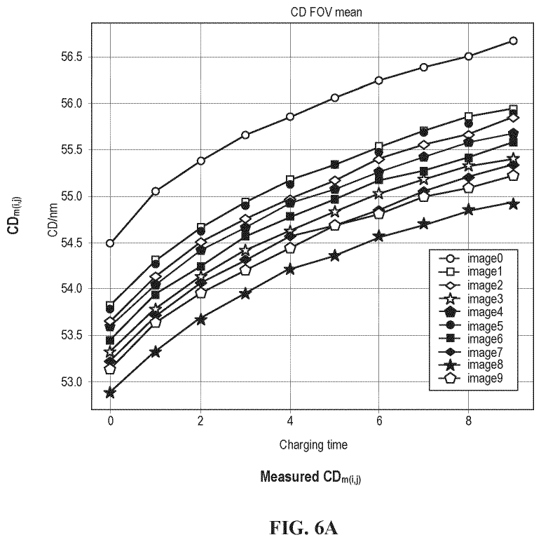

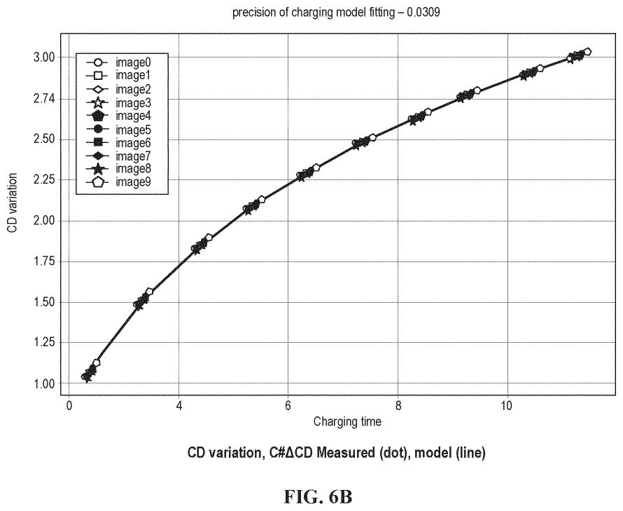

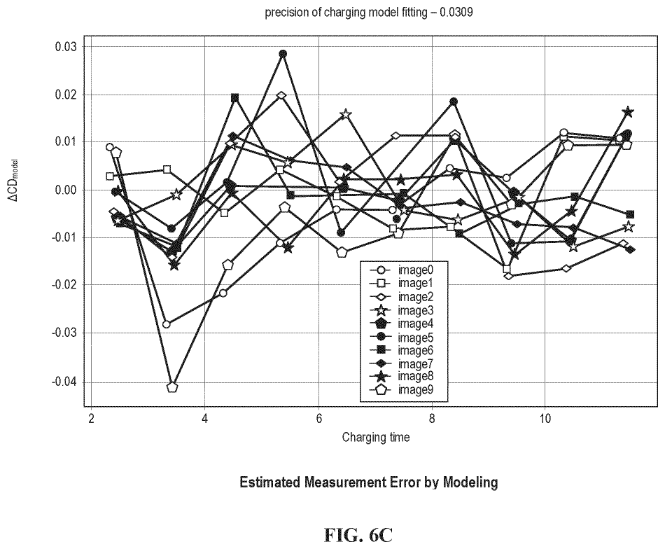

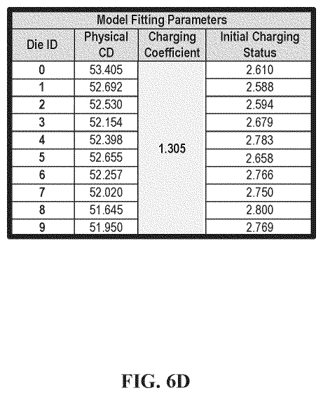

FIGS. 6A-D illustrate example experimental plots of CD vs. charging time, consistent with embodiments of the present disclosure. FIG. 6A shows an example plot of measurements CD_{m(i,j)} as a function of charging time index i for 10 die locations over 10 runs, or i=j=10. This plot may be an example of the raw data of box 1 in FIG. 5. FIG. 6B shows the example plot of CD variation with charging time, with the dots indicating actual measurements from FIG. 6A and the line representing a model. For example, the line may correspond to models having the form of eqn. 5 and the data shown at box 5 of FIG. 5. Finally, FIG. 6C shows an example plot of an estimated measurement error, ΔCD_{m(i,j)}. The example data illustrated in FIGS. 6A-D indicate that charged particle beam inspection processes may be significantly improved in accuracy and precision by employing charging models according to embodiments of the present disclosure. Example model fitting parameters for physical CD aⱼ, charging coefficient b, and initial charging status cⱼ are given at FIG. 6D.

It is noted that some embodiments are disclosed with respect to a particular class of charged particle beam inspections, such as CD measurement in an electron beam apparatus. However, it should be understood that embodiments of the present disclosure are not limited to this. For example, other inspection systems, such as proton or other ion beam systems, x-ray, EUV, etc. may be used. Further, in some embodiments, other inspection processes, such as defect inspection, or alignment, overlay or other metrology operations, may be performed in an analogous manner.

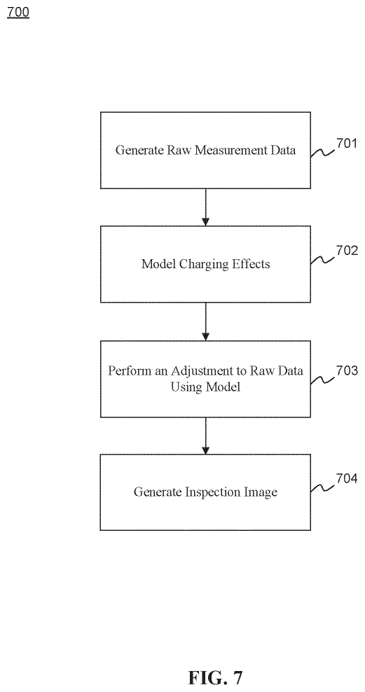

FIG. 7 illustrates a charged particle exposure method, consistent with embodiments of the present disclosure. Method 700 may be performed using a charged article beam apparatus such as, e.g., any of apparatus 100, 100A, or 100B of FIGS. 1-2B. At step 701, a measurement process may be performed on a sample, such as a semiconductor wafer, to generate raw measurement data. For example, a measurement X_{i,j} may be performed for the i^{th} measurement X at the j^{th} position on a wafer, where i=1 . . . k and j=1 . . . 1. Measurement X may be, e.g., a CD measurement. Alternatively, X may comprise another metrology parameter, an alignment or overlay parameter, a defect inspection, or other measurement as discussed above.

At step 702, a model of charging effects may be constructed. The model may comprise a first term representing the true physical parameter associated with the measurement. The model may comprise a second term including a charging coefficient and a charging function having an initial charging status term. For example, in some embodiments the model may take the form:

$${X}_{m o d e l ( i j )} = {a}_{j} + b * ln ( i + {c}_{j} ) ≅ {X}_{j}^{*} + {X}_{i , j}^{\#} \qquad ( eqn . 8 )$$

where aⱼ may be an actual value of the measured parameter X, b may be a charging coefficient, and ln(i+cⱼ) may be a charging function, i may represent a run index or other charging time index, and cⱼ may be an initial charging status.

At step 703, an adjustment may be performed to the raw data generated at step 701 using the model of step 702. In some embodiments, the adjustment may comprise a correction to the measurement data based on the modeled charging effects. In some embodiments, the adjustment may comprise a calculation of measurement precision as discussed above with respect to FIG. 5. In some embodiments, the adjustment may comprise a calculation to identify a charging coefficient of one or more features on the sample.

Step 704 may optionally include generating an inspection image. For example, the inspection image may comprise a frame average, or other integration, of the measurement scans i=1 . . . k. the image may comprise corrections to distortion or other image aberrations based on the modeled charging effects of step 702. The inspection image may reproduce the actual feature layout of the sample with greater accuracy than would be achieved without modeling the charging effects. The inspection image may be used to evaluate metrology or defect inspection parameters, such as CD, linewidth or line edge roughness, edge placement error, sidewall angle, alignment, overlay, or other parameters.

The steps illustrated above in method 700 are not necessarily performed in the order presented, and may be performed concurrently, or in orders other than what is presented above. By way of example, step 702 may be performed before, after or concurrently with step 701. Further, not all steps are necessarily performed in all embodiments of the method 700. For example, some embodiments in which step 703 comprises a calculation of CD precision may not additionally include a step at 704 of generating an inspection image.

Embodiments of the present disclosure may further be described using the following clauses:
1. A charged particle beam method, comprising:
performing a first measurement of a parameter of a feature on a sample using a first scan of a charged particle beam apparatus;
performing a second measurement of the parameter of the feature on the sample using a second scan of the charged particle beam apparatus;
estimating a first value of a charging effect on the feature for the first scan and a second value of the charging effect on the feature for the second scan based on a charging effect model; and
adjusting data from the first measurement and the second measurement based on the first value and the second value.
2. The charged particle beam method of clause 1, wherein the charging effect model comprises a function representing a change in the charging effect as a function of charging time.
3. The charged particle beam method of clause 2, wherein the charging time is based on a number of scans of the feature.
4. The charged particle beam method of clause 2, wherein the charging effect model comprises a term representing a physical value of the parameter.
5. The charged particle beam method of clause 2, wherein the charging effect model comprises a term representing an initial charging status of the feature.
6. The charged particle beam method of clause 2, wherein the charging effect model comprises a term representing a charging coefficient of the feature.
7. The charged particle beam method of clause 2, wherein the charging effect model comprises a logarithmic function.
8. The charged particle beam method of clause 7, wherein an argument of the logarithmic function comprises a first term representing a charging time of the feature and a second term representing an initial charging status of the feature.
9. The charged particle beam method of clause 2, wherein the charging effect model comprises one of an exponential function, a polynomial function, or a hyperbolic function.
10. The charged particle beam method of clause 1, wherein the first value has a greater magnitude than the second value.
11. The charged particle beam method of clause 1, wherein the parameter comprises a critical dimension measurement of the feature.
12. The charged particle beam method of clause 1, wherein the parameter comprises one of a line width, line edge roughness, alignment, overlay, or sidewall angle parameter.
13. The charged particle beam method of clause 1, wherein the parameter comprises a defect parameter.
14. The charged particle beam method of clause 1, wherein the feature comprises a feature of a line and space pattern.
15. The charged particle beam method of clause 1, wherein adjusting data from the first measurement and the second measurement comprises performing a correction of the first measurement and the second measurement to compensate for the charging effect on the feature.
16. The charged particle beam method of clause 1, wherein adjusting data from the first measurement and the second measurement comprises calculating a measurement precision based on the first measurement, the second measurement, the first value, and the second value.
17. The charged particle beam method of clause 1, further comprising:
generating an inspection image based on the first measurement, the second measurement, the first value, and the second value,
wherein adjusting data from the first measurement and the second measurement comprises correcting an imaging error of the inspection image based on the first measurement, the second measurement, the first value, and the second value.
18. The charged particle beam method of clause 1, wherein the charged particle beam apparatus comprises an electron beam apparatus.
19. A non-transitory computer-readable medium storing a set of instructions that are executable by at least one processor of a device to cause the device to perform operations comprising:
performing a first measurement of a parameter of a feature on a sample using a first scan of a charged particle beam apparatus;
performing a second measurement of the parameter of the feature on the sample using a second scan of the charged particle beam apparatus;
estimating a first value of a charging effect on the feature for the first scan and a second value of the charging effect on the feature for the second scan based on a charging effect model; and
adjusting data from the first measurement and the second measurement based on the first value and the second value.
20. The non-transitory computer-readable medium of clause 19, wherein the charging effect model comprises a function representing a change in the charging effect as a function of charging time.
21. The non-transitory computer-readable medium of clause 20, wherein the charging time is based on a number of scans of the feature.
22. The non-transitory computer-readable medium of clause 20, wherein the charging effect model comprises a term representing a physical value of the parameter.
23. The non-transitory computer-readable medium of clause 20, wherein the charging effect model comprises a term representing an initial charging status of the feature.
24. The non-transitory computer-readable medium of clause 20, wherein the charging effect model comprises a term representing a charging coefficient of the feature.
25. The non-transitory computer-readable medium of clause 20, wherein the charging effect model comprises a logarithmic function.
26. The non-transitory computer-readable medium of clause 25, wherein an argument of the logarithmic function comprises a first term representing a charging time of the feature and a second term representing an initial charging status of the feature.
27. The non-transitory computer-readable medium of clause 20, wherein the charging effect model comprises one of an exponential function, a polynomial function, or a hyperbolic function.
28. The non-transitory computer-readable medium of clause 19, wherein the first value has a greater magnitude than the second value.
29. The non-transitory computer-readable medium of clause 19, wherein the parameter comprises a critical dimension measurement of the feature.
30. The non-transitory computer-readable medium of clause 19, wherein the parameter comprises one of a line width, line edge roughness, alignment, overlay, or sidewall angle parameter.
31. The non-transitory computer-readable medium of clause 19, wherein the parameter comprises a defect parameter.
32. The non-transitory computer-readable medium of clause 19, wherein the feature comprises a feature of a line and space pattern.
33. The non-transitory computer-readable medium of clause 19, wherein adjusting data from the first measurement and the second measurement comprises performing a correction of the first measurement and the second measurement to compensate for the charging effect on the feature.
34. The non-transitory computer-readable medium of clause 19, wherein adjusting data from the first measurement and the second measurement comprises calculating a measurement precision based on the first measurement, the second measurement, the first value, and the second value.
35. The non-transitory computer-readable medium of clause 19, wherein the set of instructions that are executable by the at least one processor cause the device to further perform:
generating an inspection image based on the first measurement, the second measurement, the first value, and the second value,
wherein adjusting data from the first measurement and the second measurement comprises correcting an imaging error of the inspection image based on the first measurement, the second measurement, the first value, and the second value.
36. The non-transitory computer-readable medium of clause 19, wherein the charged particle beam apparatus comprises an electron beam apparatus.
37. A charged particle beam apparatus, comprising:
a charged particle beam source configured to generate a beam of primary charged particles; an optical system configured to direct the beam of primary charged particles at a sample surface to inspect the sample surface;
a charged particle detector configured to detect charged particles returned from the sample surface; a controller comprising one or more processors and configured to cause the charged particle beam apparatus to perform operations comprising:
performing a first measurement of a parameter of a feature on the sample using a first scan of the charged particle beam apparatus;
performing a second measurement of the parameter of the feature on the sample using a second scan of the charged particle beam apparatus;
estimating a first value of a charging effect on the feature for the first scan and a second value of the charging effect on the feature for the second scan based on a charging effect model; and adjusting data from the first measurement and the second measurement based on the first value and the second value.
38. The charged particle beam apparatus of clause 37, wherein the charging effect model comprises a function representing a change in the charging effect as a function of charging time.
39. The charged particle beam apparatus of clause 38, wherein the charging time is based on a number of scans of the feature.
40. The charged particle beam apparatus of clause 38, wherein the charging effect model comprises a term representing a physical value of the parameter.
41. The charged particle beam apparatus of clause 38, wherein the charging effect model comprises a term representing an initial charging status of the feature.
42. The charged particle beam apparatus of clause 38, wherein the charging effect model comprises a term representing a charging coefficient of the feature.
43. The charged particle beam apparatus of clause 38, wherein the charging effect model comprises a logarithmic function.
44. The charged particle beam apparatus of clause 43, wherein an argument of the logarithmic function comprises a first term representing a charging time of the feature and a second term representing an initial charging status of the feature.
45. The charged particle beam apparatus of clause 38, wherein the charging effect model comprises one of an exponential function, a polynomial function, or a hyperbolic function.
46. The charged particle beam apparatus of clause 37, wherein the first value has a greater magnitude than the second value.
47. The charged particle beam apparatus of clause 37, wherein the parameter comprises a critical dimension measurement of the feature.
48. The charged particle beam apparatus of clause 37, wherein the parameter comprises one of a line width, line edge roughness, alignment, overlay, or sidewall angle parameter.
49. The charged particle beam apparatus of clause 37, wherein the parameter comprises a defect parameter.
50. The charged particle beam apparatus of clause 37, wherein the feature comprises a feature of a line and space pattern.
51. The charged particle beam apparatus of clause 37, wherein adjusting data from the first measurement and the second measurement comprises performing a correction of the first measurement and the second measurement to compensate for the charging effect on the feature.
52. The charged particle beam apparatus of clause 37, wherein adjusting data from the first measurement and the second measurement comprises calculating a measurement precision based on the first measurement, the second measurement, the first value, and the second value.
53. The charged particle beam apparatus of clause 37, wherein the controller comprising one or more processors is configured to cause the charged particle beam apparatus to further perform:
generating an inspection image based on the first measurement, the second measurement, the first value, and the second value,
wherein adjusting data from the first measurement and the second measurement comprises correcting an imaging error of the inspection image based on the first measurement, the second measurement, the first value, and the second value.
54. The charged particle beam apparatus of clause 37, wherein the charged particle beam apparatus comprises an electron beam apparatus.
55. A charged particle beam method, comprising:
performing a plurality of measurements of a parameter of a feature on a sample using a plurality of scans of a charged particle beam apparatus;
estimating charging effects on the feature for the plurality of measurements using a charging effect model; and
adjusting the plurality of measurements based on the estimated charging effects to yield a plurality of corrected measurements; and
generating an inspection result based on the plurality of corrected measurements.
56. The charged particle beam method of clause 55, wherein the charging effect model comprises a function representing a change in the charging effect as a function of charging time.
57. The charged particle beam method of clause 56, wherein the charging time is based on a number of scans of the feature.
58. The charged particle beam method of clause 56, wherein the charging effect model comprises a term representing a physical value of the parameter.
59. The charged particle beam method of clause 56, wherein the charging effect model comprises a term representing an initial charging status of the feature.
60. The charged particle beam method of clause 56, wherein the charging effect model comprises a term representing a charging coefficient of the feature.
61. The charged particle beam method of clause 56, wherein the charging effect model comprises a logarithmic function.
62. The charged particle beam method of clause 61, wherein an argument of the logarithmic function comprises a first term representing a charging time of the feature and a second term representing an initial charging status of the feature.
63. The charged particle beam method of clause 56, wherein the charging effect model comprises one of an exponential function, a polynomial function, or a hyperbolic function.
64. The charged particle beam method of clause 55, wherein the parameter comprises a critical dimension measurement of the feature.
65. The charged particle beam method of clause 55, wherein the parameter comprises one of a line width, line edge roughness, alignment, overlay, or sidewall angle parameter.
66. The charged particle beam method of clause 55, wherein the parameter comprises a defect parameter.
67. The charged particle beam method of clause 55, wherein the feature comprises a feature of a line and space pattern.
68. The charged particle beam method of clause 55, wherein adjusting data from the first measurement and the second measurement comprises performing a correction of the first measurement and the second measurement to compensate for the charging effect on the feature.
69. The charged particle beam method of clause 55, wherein adjusting the plurality of measurements comprises calculating a measurement precision based the plurality of measurements and a plurality of estimated charging effect values for the plurality of measurements.
70. The charged particle beam method of clause 55, further comprising:
generating an inspection image based on the plurality of measurements and a plurality of estimated charging effect values for the plurality of measurements,
wherein adjusting data from based the plurality of measurements comprises correcting an imaging error of the inspection image based on the plurality of measurements and the plurality of estimated charging effect values.
71. The charged particle beam method of clause 55, wherein the charged particle beam apparatus comprises an electron beam apparatus.

A non-transitory computer-readable medium may be provided that stores instructions for a processor of a controller (e.g., controller 109 in FIGS. 1 or 2B, or image processing system 199 of FIG. 2B) for detecting charged particles according to, e.g., the exemplary flowcharts of FIG. 700, consistent with embodiments of the present disclosure. For example, the instructions stored in the non-transitory computer-readable medium may be executed by the circuitry of the controller for performing method 700 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes can be made without departing from the scope thereof. For example, a charged particle inspection system may be but one example of a charged particle beam system consistent with embodiments of the present disclosure.

1. A non-transitory computer-readable medium storing a set of instructions that are executable by at least one processor of a device to cause the device to perform operations comprising:
performing a first measurement of a parameter of a feature on a sample using a first scan of a charged particle beam apparatus;
performing a second measurement of the parameter of the feature on the sample using a second scan of the charged particle beam apparatus;
estimating a first value of a charging effect on the feature for the first scan and a second value of the charging effect on the feature for the second scan based on a charging effect model; and
adjusting data from the first measurement and the second measurement based on the first value and the second value.

2. The non-transitory computer-readable medium of claim 1, wherein the charging effect model comprises a function representing a change in the charging effect as a function of charging time.

3. The non-transitory computer-readable medium of claim 2, wherein the charging time is based on a number of scans of the feature.

4. The non-transitory computer-readable medium of claim 2, wherein the charging effect model comprises a term representing a physical value of the parameter.

5. The non-transitory computer-readable medium of claim 2, wherein the charging effect model comprises a term representing an initial charging status of the feature.

6. The non-transitory computer-readable medium of claim 2, wherein the charging effect model comprises a term representing a charging coefficient of the feature.

7. The non-transitory computer-readable medium of claim 2, wherein the charging effect model comprises a logarithmic function.

8. The non-transitory computer-readable medium of claim 7, wherein an argument of the logarithmic function comprises a first term representing a charging time of the feature and a second term representing an initial charging status of the feature.

9. The non-transitory computer-readable medium of claim 2, wherein the charging effect model comprises one of an exponential function, a polynomial function, or a hyperbolic function.

10. The non-transitory computer-readable medium of claim 1, wherein the first value has a greater magnitude than the second value.

11. The non-transitory computer-readable medium of claim 1, wherein the parameter comprises a critical dimension measurement of the feature.

12. The non-transitory computer-readable medium of claim 1, wherein the parameter comprises one of a line width, line edge roughness, alignment, overlay, or sidewall angle parameter.

13. The non-transitory computer-readable medium of claim 1, wherein the parameter comprises a defect parameter.

14. The non-transitory computer-readable medium of claim 1, wherein the feature comprises a feature of a line and space pattern

15. The non-transitory computer-readable medium of claim 1, wherein adjusting data from the first measurement and the second measurement comprises performing a correction of the first measurement and the second measurement to compensate for the charging effect on the feature.

16. A charged particle beam apparatus, comprising:
a charged particle beam source configured to generate a beam of primary charged particles;
an optical system configured to direct the beam of primary charged particles at a sample surface to inspect the sample surface;
a charged particle detector configured to detect charged particles returned from the sample surface;
a controller comprising one or more processors and configured to cause the charged particle beam apparatus to perform operations comprising:
performing a first measurement of a parameter of a feature on the sample using a first scan of the charged particle beam apparatus;
performing a second measurement of the parameter of the feature on the sample using a second scan of the charged particle beam apparatus;
estimating a first value of a charging effect on the feature for the first scan and a second value of the charging effect on the feature for the second scan based on a charging effect model; and
adjusting data from the first measurement and the second measurement based on the first value and the second value.

17. The charged particle beam apparatus of claim 16, wherein the charging effect model comprises a function representing a change in the charging effect as a function of charging time.

18. The charged particle beam apparatus of claim 17, wherein the charging time is based on a number of scans of the feature.

19. The charged particle beam apparatus of claim 17, wherein the charging effect model comprises a term representing a physical value of the parameter.

20. The charged particle beam apparatus of claim 17, wherein the charging effect model comprises a term representing an initial charging status of the feature.
